(19) United States
(12) Patent Application Publication
(10) Pub. No.: US 2011/0083960 A1
(43) Pub. Date: Apr. 14, 2011

(54) SPUTTERING APPARATUS

(75) Inventors: TAE-HOON YANG, Yongin-City (KR); KI-YONG LEE, Yongin-City (KR); JIN-WOOK SEO, Yongin-City (KR); BYOUNG-KEON PARK, Yongin-City (KR); YUN-MO CHUNG, Yongin-City (KR); DONG-HYUN LEE, Yongin-City (KR); KIL-WON LEE, Yongin-City (KR); JAE-WAN JUNG, Yongin-City (KR); JONG-RYUK PARK, Yongin-City (KR); BO-KYUNG CHOI, Yongin-City (KR); WON-BONG BAEK, Yongin-City (KR); BYUNG-SOO SO, Yongin-City (KR); JONG-WON HONG, Yongin-City (KR); MIN-JAE JEONG, Yongin-City (KR); HEUNG-YEOL NA, Yongin-City (KR); IVAN MAIDANCHUK, Yongin-City (KR); EU-GENE KANG, Yongin-City (KR); SEOK-RAK CHANG, Yongin-City (KR)

(73) Assignee: SAMSUNG MOBILE DISPLAY CO., LTD., Yongin-City (KR)

(21) Appl. No.: 12/902,660

(22) Filed: Oct. 12, 2010

(30) Foreign Application Priority Data
Oct. 12, 2009 (KR) 10-2009-0096978

(51) Int. Cl. C23C 14/34

(52) U.S. Cl. 204/298.07

(57) ABSTRACT

A sputtering apparatus that is capable of uniformly depositing an ultra-low concentration metal catalyst on a substrate having an amorphous silicon layer in order to crystallize the amorphous silicon layer. The sputtering apparatus includes a process chamber, a metal target located inside the process chamber, a substrate holder located opposite the metal target, and a vacuum pump connected with an exhaust pipe of the process chamber. An area of the metal target is more than 1.3 times an area of a substrate placed on the substrate holder.

### CLAIM OR PFIORITY

This application makes reference to, incorporates into this specification the entire contents of, and claims all benefits accruing under 35 U.S.C. §119 from an application earlier filed in the Korean Intellectual Property Office filed on Oct. 12, 2009 and there duly assigned Serial No. 10-2009-0096978.

### BACKGROUND OF THE INVENTION

1. Field of the Invention

An aspect of the present invention relates to a sputtering apparatus.

2. Description of the Related Art

Flat panel display devices have replaced cathode ray tube display devices due to characteristics such as light weight, thin thickness, and so on, and typical examples thereof include liquid crystal displays (LCDs) and organic light emitting diode display devices (OLEDs). In comparison with the LCDs, the OLEDs are excellent in brightness and viewing angle characteristics and require no backlight, so that they can be realized as ultra thin displays.

The OLEDs are classified into two types, a passive matrix type and an active matrix type, according to a driving type. The active matrix type OLEDs include a circuit using a thin film transistor (TFT).

The TFT generally includes a semiconductor layer having source, drain, and channel regions, a gate electrode, a source electrode, and a drain electrode. The semiconductor layer may be formed of polycrystalline silicon (poly-Si) or amorphous silicon (a-Si). The poly-Si has a higher electron mobility than the a-Si. Thus, the poly-Si is mainly applied at present.

The above information disclosed in this Related Art section is only for enhancement of understanding of the background of the invention and therefore it may contain information that does not form the prior art that is already known to a person of ordinary skill in the art.

### SUMMARY OF THE INVENTION

Aspects of the present invention provide a sputtering apparatus capable of uniformly depositing an ultra-low concentration metal catalyst on a substrate having an amorphous silicon layer even when no magnetic assembly is used to prevent magnetization of the metal catalyst and deposit the metal catalyst at an ultra-low concentration.

According to an exemplary embodiment of the present invention, a sputtering apparatus includes a process chamber, a metal target located inside the process chamber, a substrate holder located opposite the metal target, and a vacuum pump connected with an exhaust pipe of the process chamber. An area d2 of the metal target is more than 1.3 times an area d1 of a substrate 180 placed on the substrate holder.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 schematically illustrates a sputtering apparatus according to an exemplary embodiment of the present invention; and

FIG. 2 is a graph showing a non-uniformity rate of a metal catalyst deposited on the edge of a substrate according to an area ratio of a metal target to the substrate in a sputtering apparatus.

### DETAILED DESCRIPTION OF THE INVENTION

Reference will now be made in detail to the present embodiments of the present invention, examples of which are shown in the accompanying drawings, wherein like reference numerals refer to the like elements throughout. In the drawings, the thicknesses of layers and regions may be exaggerated for clarity. The embodiments are described below in order to explain the present invention by referring to the figures.

In order to clarify the present invention, elements extrinsic to the description are omitted from the details of this description, and like reference numerals refer to like elements throughout the specification.

In several exemplary embodiments, constituent elements having the same configuration are representatively described in a first exemplary embodiment by using the same reference numeral and only constituent elements other than the constituent elements described in the first exemplary embodiment will be described in other embodiments.

Among the methods of crystallizing the a-Si into the poly-Si to create a semiconductor layer of a TFT, one uses a metal. The crystallizing method using the metal involves depositing a metal catalyst on a substrate using a process such as a sputtering process of depositing a metal layer on a substrate by applying plasma to a metal target formed of a crystallization inducing metal such as nickel, or an atomic layer deposition (ALD) process of forming an atomic layer of a metal catalyst, as a crystallization inducing metal such as nickel, on a substrate using a chemical method based on a reaction gas containing the metal catalyst, and crystallizing the a-Si using the metal catalyst as a seed. This method has an advantage of crystallizing the a-Si at a relatively low temperature for a short time.

Typical sputtering apparatuses are designed to concentrate the plasma on the metal target and substrate using a magnetic assembly located at the rear of the metal target and uniformly deposit a thick layer in a short time. However, because in the crystallizing method using the metal, the metal catalyst should be deposited on the substrate having the a-Si layer at an ultra-low concentration in order to improve characteristics of the TFT using the poly-Si, sputtering apparatuses used in the crystallizing method using the metal should exclude such a magnetic assembly to prevent magnetization of the metal catalyst discharged from the crystallization inducing metal such as nickel as well as to deposit the metal catalyst at an ultra-low concentration.

The sputtering apparatuses in which the magnetic assembly is not used may deposit the ultra-low concentration metal catalyst on the substrate. However, the metal catalyst is non-uniformly deposited on an edge of the substrate.

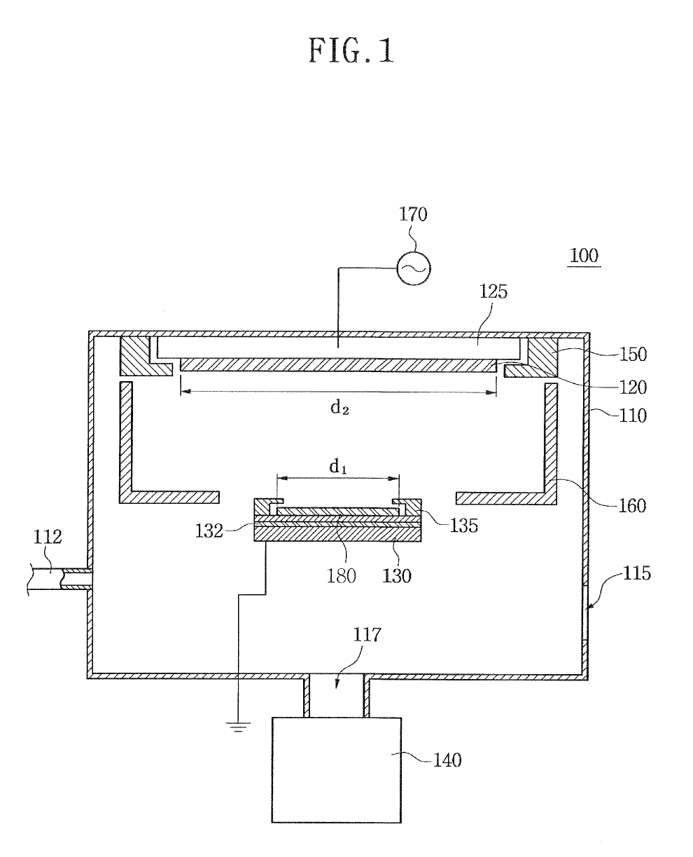

FIG. 1 schematically illustrates a sputtering apparatus according to an exemplary embodiment of the present invention.

Referring to FIG. 1, a sputtering apparatus 100 according to an exemplary embodiment of the present invention includes a process chamber 110 providing a space for a sputtering process, a metal target 120 located inside the process chamber 110 and formed of a crystallization inducing metal such as nickel, a substrate holder 130 located opposite the metal target 120 and holding a substrate having an amorphous silicon layer, and a vacuum pump 140 connected with an exhaust pipe 117 of the process chamber 110.

The process chamber 110 is to provide the space in which the sputtering process is carried out, and includes an intake pipe 112 supplying a reaction gas for generating plasma between the metal target 120 and the substrate holder 130, and an exhaust pipe 117 controlling a pressure in the process chamber 110 and exhausting a remaining reaction gas. The process chamber 110 may further include a first shield 150 controlling a flow direction of the metal catalyst discharged from the metal target. Here, the reaction gas may be argon (Ar) gas.

Further, the process chamber 110 includes a first electrode 125 interposed between the metal target 120 and the process chamber 110 and a second electrode 132 installed in the substrate holder 130 in order to generate the plasma between the metal target 120 and the substrate holder 130. The first and second electrodes 125 and 132 are configured to be supplied with voltages of different polarities, respectively. Here, to facilitate control of the plasma generated between the metal target 120 and the substrate holder 130 and deposit the metal catalyst on the substrate 180, the second electrode 132 may be connected to a reference power supply, and the first electrode 125 may be connected to a power supply 170 from which a constant direct current (DC) voltage is supplied.

The process chamber 110 includes a gate 115 through which the substrate 180 is carried into and out of the process chamber 110. To prevent the plasma from damaging an amorphous or polycrystalline silicon layer on the substrate carried into and out of the process chamber 110 through the gate 115 as well as to prevent unnecessary plasma from being generated, the process chamber 110 may further include a second shield 160, which isolates the gate 115 from the plasma generating region located between the metal target 120 and the substrate holder 130. In this case, the process chamber 110 may further include a transfer unit (not shown), which transfers the substrate holder 130, on which the substrate 180 is loaded through the gate 115, from the side of the gate 115 to the inside of the second shield 160.

Here, the intake pipe 112 may be configured such that the reaction gas is supplied into the process chamber 110, particularly between the metal target 120 and the substrate holder 130 through the second shield 160. However, to deposit the ultra-low concentration metal catalyst on the substrate 180, as shown in FIG. 1, the intake pipe 112 may be supplied into an internal space of the process chamber 110 which is not surrounded by the second shield 160, i.e. a space between the process chamber 110 and the second shield 160.

The substrate holder 130 may include a clamping member 135 clamping the substrate 180. To prevent the substrate 180 from being damaged when the substrate holder 130 is transferred by the transfer unit, the clamping member 135 may be configured to surround an edge of the substrate 180. Here, the edge of the substrate 180 which is surrounded by the clamping member 135 may be a peripheral region that is not used for the thin film transistor because the metal catalyst is not deposited thereon by the sputtering process.

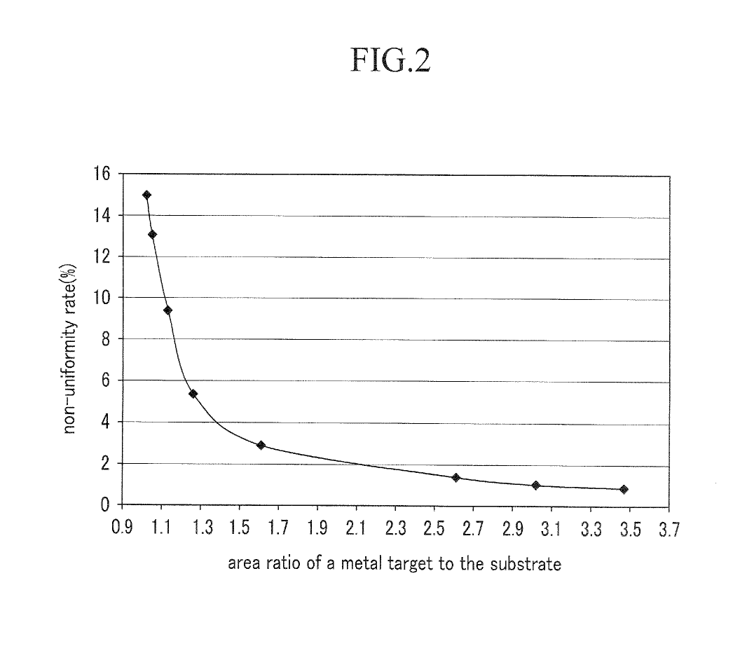

FIG. 2 is a graph showing a non-uniformity rate of a metal catalyst deposited on the edge of a substrate according to an area ratio of a metal target to the substrate in a sputtering apparatus in accordance with an exemplary embodiment of the present invention.

Referring to FIG. 2, it can be found that, when an area ratio of the metal target to the substrate is less than 1.3, i.e. when the area of the metal target is less than 1.3 times the area of the substrate, a non-uniformity rate of the metal catalyst deposited on an edge of the substrate is sharply varied, and that, when the area ratio of the metal target to the substrate is more than 1.3, i.e. when the area of the metal target is more than 1.3 times the area of the substrate, the non-uniformity rate of the metal catalyst deposited on the edge of the substrate is slowly varied.

Thus, in the sputtering apparatus without a magnetic assembly, when the area ratio of the metal target to the substrate is set to 1.3 or more, i.e. when the area d2 of the metal target is set to be more than 1.3 times the area d1 of the substrate, the non-uniformity rate of the metal catalyst deposited on the edge of the substrate is reduced, so that the metal catalyst can be more uniformly deposited on the substrate.

As illustrated in FIG. 2, as the area ratio of the metal target to the substrate increases, the non-uniformity rate of the metal catalyst deposited on the edge of the substrate is reduced. However, there is a typical problem in that, when the area of the metal target is increased, an entire size of the sputtering apparatus is increased.

Further, as the area d2 of the metal target increases, an area of the first electrode is increased. As the area of the first electrode increases, the plasma generated between the metal target and the substrate is concentrated on one side due to voltage drop. Thus, since the metal catalyst deposited on the substrate may become non-uniform, the area d2 of the metal target is preferably less than 3 times the area d1 of the substrate.

Consequently, the sputtering apparatus according to an exemplary embodiment of the present invention is configured to control the area of the metal target formed of the crystallization inducing metal such as nickel to be more than 1.3 times, preferably to range from 1.3 times to 3 times, and thus reduce the non-uniformity rate of the metal catalyst deposited on the edge of the substrate, so that it can uniformly deposit the ultra-low concentration metal catalyst on the substrate having the amorphous silicon layer.

Thus, a sputtering apparatus according to an exemplary embodiment of the present invention is configured to set the area d2 of a metal target to be more than 1.3 times the area d1 of a substrate, and thus reduce a non-uniformity rate of a metal catalyst deposited on an edge of the substrate even when no magnetic assembly is used to prevent magnetization of the metal catalyst and deposit the metal catalyst at an ultra-low concentration, so that the ultra-low concentration metal catalyst can be uniformly deposited on the substrate.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A sputtering apparatus comprising:
a process chamber;
a metal target located inside the process chamber;
a substrate holder located opposite the metal target to hold a substrate; and
a vacuum pump connected with an exhaust pipe of the process chamber,
wherein an area of the metal target is more than 1.3 times an area of the substrate placed on the substrate holder.

2. The sputtering apparatus according to claim 1, wherein the area of the metal target ranges from 1.3 times to 3 times the area of the substrate.

3. The sputtering apparatus according to claim 1, further comprising a first shield, which is located around the metal target and controls a flow direction of a metal catalyst discharged from the metal target.

4. The sputtering apparatus according to claim 1, further comprising a second shield, which surrounds a plasma generating region between the metal target and the substrate holder.

5. The sputtering apparatus according to claim 4, wherein the process chamber includes:
a depositing region which is surrounded by the second shield and in which a sputtering process is performed;
a substrate carrying region through which the substrate is carried into and out of the process chamber; and
a transfer unit configured to transfer the substrate holder between the depositing region and the substrate carrying region.

6. The sputtering apparatus according to claim 4, further comprising an intake pipe configured to introduce a reaction gas for generating plasma into the process chamber, wherein the intake pipe introduces the reaction gas into a space between the process chamber and the second shield.

7. The sputtering apparatus according to claim 6, wherein the reaction gas includes argon gas.

8. The sputtering apparatus according to claim 1, wherein the substrate holder includes a clamping member clamping the substrate.

9. The sputtering apparatus according to claim 8, wherein the clamping member is located to surround an edge of the substrate.

10. The sputtering apparatus according to claim 1, wherein the metal target includes nickel.

11. The sputtering apparatus according to claim 1, wherein the process chamber includes a first electrode interposed between the metal target and the process chamber and a second electrode installed in the substrate holder, and the first and second electrodes are supplied with voltages having different polarities, respectively.

12. The sputtering apparatus according to claim 11, wherein the second electrode is connected to a reference power supply, and the first electrode is connected to a power supply that supplies direct current (DC) power.

13. A sputtering apparatus comprising:
a process chamber;
a metal target located inside the process chamber;
a substrate;
a substrate holder located opposite the metal target to hold the substrate; and
a vacuum pump connected with an exhaust pipe of the process chamber,
wherein an area ratio of the metal target to the substrate is in a range of equal to or greater than 1.3 to less than or equal to 3.0.

14. The sputtering apparatus according to claim 13, further comprising a first shield, which is located around the metal target and controls a flow direction of a metal catalyst discharged from the metal target.

15. The sputtering apparatus according to claim 13, further comprising a second shield, which surrounds a plasma generating region between the metal target and the substrate holder.

16. The sputtering apparatus according to claim 15, wherein the process chamber includes:
a depositing region which is surrounded by the second shield and in which a sputtering process is performed;
a substrate carrying region through which the substrate is carried into and out of the process chamber; and
a transfer unit configured to transfer the substrate holder between the depositing region and the substrate carrying region.

17. The sputtering apparatus according to claim 15, further comprising an intake pipe configured to introduce a reaction gas for generating plasma into the process chamber, wherein the intake pipe introduces the reaction gas into a space between the process chamber and the second shield.

18. The sputtering apparatus according to claim 13, wherein the process chamber includes a first electrode interposed between the metal target and the process chamber and a second electrode installed in the substrate holder, and the first and second electrodes are supplied with voltages having different polarities, respectively.

19. The sputtering apparatus according to claim 18, wherein the second electrode is connected to a reference power supply, and the first electrode is connected to a power supply that supplies direct current (DC) power.

20. The sputtering apparatus according to claim 13, wherein the metal target includes nickel.
